(19) United States
(12) Patent Application Publication
(10) Pub. No.: US 2007/0227698 A1
(43) Pub. Date: Oct. 4, 2007

(54) Integrated fluid pump and radiator reservoir

(76) Inventors: Bruce R. Conway, La Honda, CA (US); Paul Tsao, Los Altos, CA (US); Tien-Chih (Eric) Lin, Fremont, CA (US); Norman Chow, Milpitas, CA (US)

Correspondence Address: HAVERSTOCK & OWENS LLP, 162 N WOLFE ROAD, SUNNYVALE, CA, 94086, US

(21) Appl. No.: 11/731,248

(22) Filed: Mar. 29, 2007

Related U.S. Application Data
(60) Provisional application No. 60/788,545, filed on Mar. 30, 2006.

(51) Int. Cl. H05K 7/20

(52) U.S. Cl. 165/80.4; 165/104.33; 361/699

(57) ABSTRACT

An integrated pumping assembly includes a pump coupled to a heat exchanging device via a mounting plate. The mounting plate is sealed to the heat exchanging device. The heat exchanging device is any fluid-based heat exchanging device, such as a fluid radiator configured to operate as a heat rejector or a heat exchanger configured to remove heat from a heat generating device. The pump is mounted directly to the mounting plate. A mounting mechanism compresses the pump housing and the mounting plate. One or more sealing washers, such as o-rings, are positioned between the pump housing and the mounting plate. The pump, mounting plate, and the heat exchanging device are aligned such that an opening in the pump housing, an opening in the mounting plate, and an opening in the housing of the heat exchanging device are aligned to form a sealed fluid path through which fluid is exchanged between the pump and the heat exchanging device.

### RELATED APPLICATIONS

This application claims priority of U.S. provisional application, Ser. No. 60/788,545, filed Mar. 30, 2006, and entitled “Multi-Chip Cooling”, by these same inventors. This application incorporates U.S. provisional application, Ser. No. 60/788,545 in its entirety by reference.

### FIELD OF THE INVENTION

The invention relates to fluid pumps in general, and specifically, to an integrated fluid pump and radiator reservoir used in a liquid cooling system.

### BACKGROUND OF THE INVENTION

Cooling of high performance processors with high heat dissipation is presenting significant challenges in the electronics cooling arena. Conventional cooling with heat pipes and fan mounted heat sinks are not adequate for cooling chips with ever increasing wattage requirements, including those exceeding 100 W.

Closed loop liquid cooling presents alternative methodologies for conventional cooling solutions. Closed loop cooling solutions more efficiently reject heat to the ambient than air cooling solutions.

FIG. 1 illustrates a conventional closed loop liquid cooling system including a pump 2, a heat rejector 4, and a heat exchanger 6, each coupled together via fluid lines 8. The heat exchanger is thermally coupled to a heat generating device 5. The pump 2 pumps and circulates fluid within the closed loop. The closed loop liquid cooling system requires that system component are sealed together in order to prevent liquid from escaping. The individual components, such as the heat rejector and the pump, are connected by the fluid lines. To properly seal this connection, each end of the fluid line must be sealed to a respective component. Components to be connected typically include barbs at the end of any input or output ports. The end of a fluid line is configured to securely fit over the barb. When two components are connected in this manner, and the components are spaced sufficiently apart, a good seal is made between the end of the fluid line and the barb on the component. However, where space limitations exist, two or more components within the cooling system may need to be spaced closely together. If the two components are positioned too closely, the barbs for each component are too close together to allow the fluid lines to conform to each barb. In this case, a proper seal is not achieved. As such, a minimum separation distance is required between each component in the cooling system. There may be configurations where the available distance to position barbs is insufficient, thereby precluding the use of barbs.

One type of pump used in a closed loop liquid cooling system is a centrifugal pump. A pumping chamber includes a rotor fitted with veins. Fluid is input to the center of the pumping chamber. As the rotor rotates, the fluid entering the center of the pumping chamber is forced outward toward the perimeter of the pumping chamber by centrifugal force. Fluid exits the pumping chamber through an outlet port configured at the outer perimeter of the pumping chamber. A disadvantage of the centrifugal pump is that in order to input fluid to the center of the pumping chamber, bending of an input fluid line is typically required. The problem is that any change in direction results in a pressure drop within the pumping system, which leads to a loss in performance. Such a result is not desirable.

### SUMMARY OF THE INVENTION

Embodiments of the present invention are directed to an integrated pumping assembly. The integrated pumping assembly includes a pump coupled to a heat exchanging device via a mounting plate. The mounting plate is sealed to the heat exchanging device. In some embodiments, the mounting plate is brazed, welded, or epoxied to the heat exchanging device. In other embodiments, the mounting plate is a machined surface of the heat exchanging device, or otherwise integrated into the heat exchanging device. The heat exchanging device is any fluid-based heat exchanging device, such as a fluid radiator configured to operate as a heat rejector or a micro-channel heat exchanger configured to remove heat from a heat generating device. The pump is mounted directly to the mounting plate. A mounting mechanism compresses the pump housing and the mounting plate. In some embodiments, one or more sealing washers, such as o-rings, are positioned between the pump housing and the mounting plate. The pump, mounting plate, and the heat exchanging device are aligned such that an opening in the pump housing, an opening in the mounting plate, and an opening in the housing of the heat exchanging device are aligned to form a sealed fluid path through which fluid can be exchanged between the pump and the heat exchanging device. In this manner, a direct fluid path between the pump and the heat exchanging device is formed.

In one aspect, an integrated pumping assembly includes a pump, a heat exchanging device, a mounting plate, and a mounting mechanism. The pump includes a first opening and a second opening through a pump housing. The heat exchanging device includes a third opening through a device housing. The mounting plate is sealed to the device housing, wherein the mounting plate includes a fourth opening aligned with the third opening in the device housing, further wherein the mounting plate is coupled to the pump housing such that the first opening in the pump housing is aligned with the fourth opening in the mounting plate. The mounting mechanism is coupled to the pump housing and to the mounting plate, wherein the mounting mechanism is configured to force the pump housing surrounding the first opening and the mounting plate surrounding the fourth opening against each other, thereby forming a sealed path through the first opening in the pump housing, the fourth opening in the mounting plate, and the third opening in the device housing. The heat exchanging device can be a fluid-based heat exchanging device. In some embodiments, the fluid-based heat exchanging device is configured to include a thermal interface. The integrated pumping assembly can also include a heat generating device coupled to the thermal interface. In some embodiments, the first opening in the pump housing is an inlet opening, the second opening in the pump housing is an outlet opening, and the third opening in the device housing is an outlet opening. In other embodiments, the first opening in the pump housing is an outlet opening, the second opening in the pump housing is an inlet opening, and the third opening in the device housing is an inlet opening. The first opening can be positioned in a first flange of the pump housing such that the first flange surrounds the first opening. In some embodiments, a portion of the first flange surrounding the first opening is configured as a flat surface and a portion of the mounting plate is configured as a flat surface, the flat surface of the mounting plate is configured to surround the fourth opening, and the integrated pumping assembly also includes one or more sealing washers positioned between the flat surface of the first flange and the flat surface of the mounting plate, wherein the one or more sealing washers surround the first opening and the fourth opening. In other embodiments, the first flange includes one or more grooves configured to surround the first opening, and the integrated assembly further comprises one or more sealing washers, one sealing washer positioned within each groove. In still other embodiments, the mounting plate includes one or more grooves configured to surround the fourth opening, and the integrated assembly further comprises one or more sealing washers, one sealing washer positioned within each groove. One or more sealing washers can form a radial seal, a face seal, or both between the mounting plate and the pump housing. The pump can be a centrifugal pump. The mounting mechanism can include a plurality of fastening mechanisms. In this case, each of the plurality of fastening mechanisms can be selected from a screw, a rivet, a cam, and a spring clip. The pump housing can also include one or more mounting flanges, each mounting flange coupled to one or more of the fastening mechanisms. The mounting mechanism can include a plurality of locking mechanisms. In this case, each of the plurality of locking mechanisms can be selected from a threading mechanism, a cam, and an interlocking mechanism. The sealed path is configured to provide direct fluid flow between the pump and the heat exchanging device. In some embodiments, the mounting plate is integrated to the heat exchanging device.

Other features and advantages of the present invention will become apparent after reviewing the detailed description of the embodiments set forth below.

### BRIEF DESCRIPTION OF THE DRAWINGS

FIG. 1 illustrates a conventional closed loop liquid cooling system.

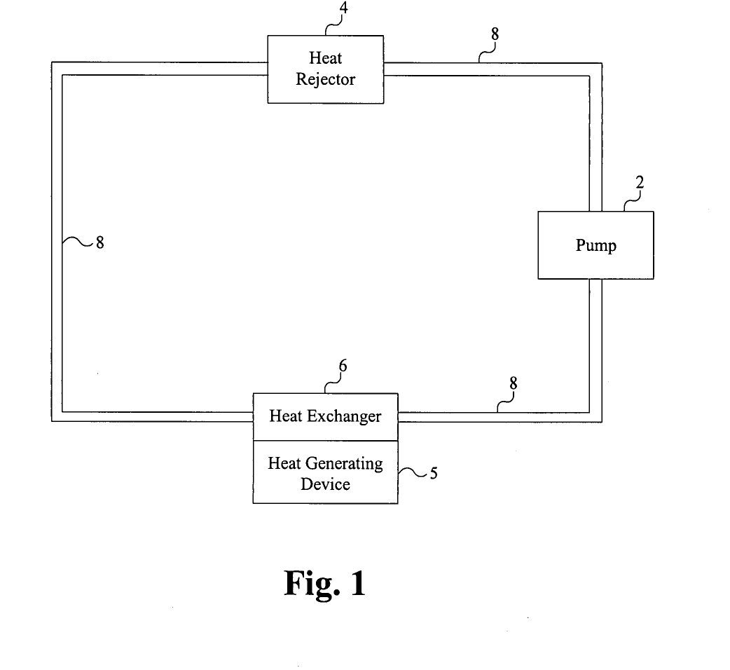

FIG. 2 illustrates a perspective view of an embodiment of the integrated pumping assembly of the present invention.

FIG. 3 illustrates a cut-out side view of the integrated pumping assembly.

The present invention is described relative to the several views of the drawings. Where appropriate and only where identical elements are disclosed and shown in more than one drawing, the same reference numeral will be used to represent such identical elements.

### DETAILED DESCRIPTION OF THE PRESENT INVENTION

The integrated pumping assembly includes a pump, a mounting plate, and a heat exchanging device configured as a single integrated assembly. In some embodiments, the heat exchanging device is a fluid radiator. The pump is fitted with a first opening and a second opening, the first opening is positioned in a flange of the pump housing. In some embodiments, the first opening is an input port and the second opening is an output port. In this case, the integrated pumping assembly is configured to pump fluid from the heat exchanging device to the pump via the input port. In other embodiments, the first opening in the pump is an output port and the second opening is an input port. In this case, the integrated pumping assembly is configured to pump fluid from the pump to the heat exchanging device. In some embodiments, a portion of the pump housing that surrounds the first opening is configured as a flat surface to be used with a sealing washer. Alternatively, a portion of the pump housing that surrounds the first opening is configured with one or more grooves to be used with one or more sealing washers.

The first opening in the pump is aligned to an opening in the mounting plate, and an opening in the mounting plate is aligned to an opening in the heat exchanging device, thereby forming a fluid path between the heat exchanging device and the pump. The heat exchanging device includes any combination of fluid reservoirs. The mounting plate is attached to the fluid radiator. The mounting plate is attached in such a manner as to form a fluid tight seal to the one or more fluid reservoir within the heat exchanging device, and to supply sufficient mechanical support for the pump. In some embodiments, a portion of the mounting plate that surrounds the mounting plate opening is configured as a flat surface to be used with one or more sealing washers. Alternatively, either a portion of the mounting plate that surrounds the mounting plate opening, a portion of the pump housing that surrounds the first opening, or both is configured with one or more grooves to be used with one or more sealing washers.

In some embodiments, the pump, and any intervening sealing devices, are secured to the mounting plate by means of a plurality of fasteners. Compression is applied by the fasteners to ensure a fluid tight seal between the pump and the mounting plate, and to ensure a fluid tight seal around both the first opening in the pump and the mounting plate opening. Alternatively, a radial type seal is formed, whereby compression to form the seal is provided by the geometry of the contact points between the mounting plate, the pump, and any intervening sealing washers. The types of fasteners include, but are not limited to, screws, rivets, cams and spring clips. In other embodiments, the pump housing and the mounting plate are designed with threading, cams or interlocks, which allow the pump and the mounting plate to be locked together without separate fasteners. In general, the components used to provide the compression force applied to the pump and to the mounting plate is referred to as a mounting mechanism.

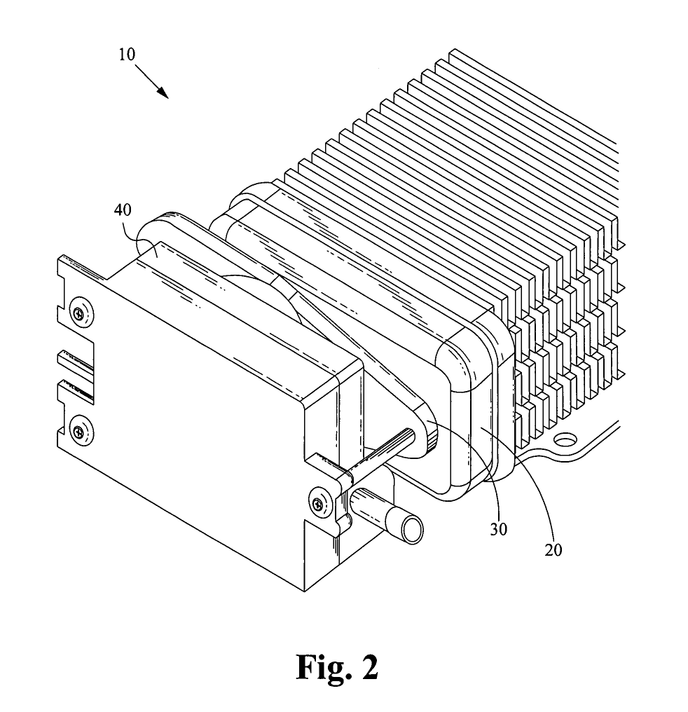

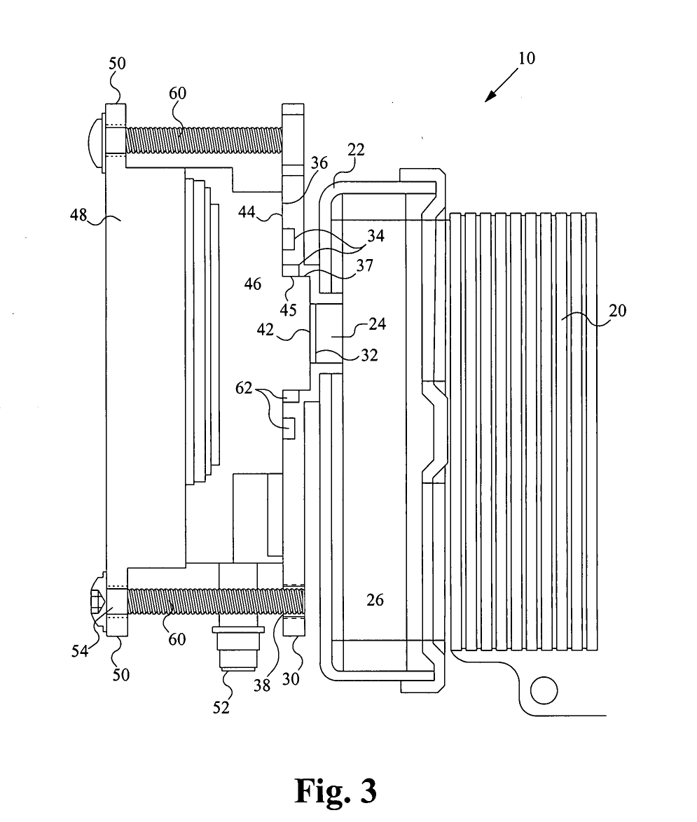

FIG. 2 illustrates a perspective view of an embodiment of the integrated pumping assembly of the present invention. The integrated pumping assembly 10 includes a heat exchanging device 20, a mounting plate 30, and a pump 40. The mounting plate 30 is attached to the heat exchanging device 20. In some embodiments, the mounting plate 30 is brazed, welded, or epoxied to the heat exchanging device 20. In general, the mounting plate 30 is attached to the heat exchanging device 20 such that a seal is formed between the two. In other embodiments, the mounting plate 30 is formed as a machined surface of the heat exchanging device 20, or otherwise integrated into the heat exchanging device 20. The pump 40 is coupled to the mounting plate 30. A mounting mechanism is used to compress the pump 40 and the mounting plate 30 against each other. The mounting mechanism and means for sealing the mounting plate 30 to the pump 40 are explained in detail below in relation to FIG. 3.

In some embodiments, the heat exchanging device 20 is a fluid-to-air heat exchanging device such as a fluid radiator. In other embodiments, the heat exchanging device 20 is a fluid-based heat exchanger configured to exchange heat between a thermally conductive material and a fluid, such as a heat exchanger coupled to a heat generating device. In this case, the heat exchanger is configured to move heat from the heat generating device to fluid flowing through the heat exchanger. In some embodiments, the pump 40 is a centrifugal pump. It is understood that any conventional type of pump can be used. In some embodiments, the pump 40 is configured to pump fluid from the heat exchanging device 20 to the pump 40. In other embodiments, the pump 40 is configured to pump fluid in the opposite direction, that is from the pump 40 to the heat exchanging device 20. For simplicity, the heat exchanging device 20 is subsequently described as a fluid radiator, and the pump 40 is configured to pump fluid from the fluid radiator 20 to the pump 40. It is understood that the following descriptions can be adapted to other types of heat exchanging devices. It is also understood that the following descriptions of the integrated pumping assembly can be adapted to a fluid flow from the pump 40 to the fluid radiator 20.

FIG. 3 illustrates a cut-out side view of the integrated pumping assembly 10. The fluid radiator 20 includes a radiator cap 22 and at least one fluid reservoir 26. The radiator cap 22 includes at least one radiator cap opening 24, which provides access to the fluid reservoir 26.

The mounting plate 30 includes at least one mounting plate opening 32. The exemplary configuration shown in FIG. 3 includes one mounting plate opening 32 and one radiator cap opening 24. The mounting plate 30 is attached to the radiator cap 22 such that the mounting plate opening 32 is aligned with the radiator cap opening 24.

The pump 40 includes a pump housing 48. A portion of the pump housing 48 is configured as a flange 46, which is coupled to the mounting plate 30. The pump housing includes a first pump opening 42 and a second pump opening 52. The first pump opening 42 is configured within the flange 46. The flange 46 is coupled to the mounting plate 30 such that the first pump opening 42 is aligned with the mounting plate opening 32 and the radiator cap opening 24, thereby forming a fluid path between the fluid reservoir 26 in the fluid radiator 20 and a pumping chamber (not shown) in the pump 40. The fluid path forms a direct path between the pump 40 and the fluid radiator 20.

A portion of the mounting plate surface is configured as a flat surface 36, and a portion of the flange surface is configured as a flat surface 44. The flat surface 36 on the mounting plate 30 is positioned so as to mate with the flat surface 44 on the flange 46. One or more grooves 34 are configured within the mating region of the mounting plate 30. A sealing washer 62 is positioned within each groove 34. The grooves 34 and the sealing washers 62 are configured to surround the mounting plate opening 32, and therefore also surround the radiator cap opening 32 and the pump opening 42.

Depending on the shape of the flange 46, one or more surface of the flange 36 are in contact with one or more surfaces of the mounting plate 30. As shown in the exemplary configuration of FIG. 3, the flange 46 is mated to the mounting plate 30 along three different surfaces. In this exemplary configuration, two grooves 34 are configured within the mounting plate 30, one groove 34 in the mating surface 36, which forms a face seal, and one groove in a mating surface 37, which forms a radial seal. The mating surface 37 is configured to mate with a mating surface 45 on the flange 46. Each of the mating surfaces 37 and 45 are configured as flat surfaces. It is understood that the pump housing 48 and the mounting plate 30 can be configured with any number of mating surfaces, and that one, some, or all of these mating surfaces can be configured with grooves and/or sealing washers.

The mating surfaces between the mounting plate 30 and the flange 46 are described above as flat surfaces. Alternatively, the mating surfaces are not flat, as long as the sealing washers make sufficient contact with the mating surfaces of both the mounting plate 30 and the flange 46 so as to provide a seal.

In an alternative configuration, the grooves 34 are not configured within the mounting plate 30, but instead, the grooves are configured within the flange 46. In another alternative configuration, grooves are configured in the mounting plate 30, as shown in FIG. 3, and grooves are configured in the flange 46. In this case, the mounting plate 30 is configured with grooves that surround the mounting plate opening 32, and the flange 46 is configured with grooves that surround the first pump opening 42. In some embodiments, the grooves in the mounting plate 30 are aligned with the grooves in the flange 46, in which case each aligned pair of grooves shares a common sealing washer. In other embodiments, the grooves in the mounting plate 30 are not aligned with the grooves in the flange 46, in which case a separate sealing washer is positioned in each groove in the mounting plate 30 and each groove in the flange 46. In yet another alternative embodiment, no grooves are configured in either the mounting plate 30 or the flange 46. In this case, one or more sealing washers are positioned between the mating surfaces of the mounting plate 30 and the flange 46.

The pump 40 is attached to the mounting plate 30 using a plurality of screws 60. The pump housing 48 includes a mounting flange 50. In some embodiments, the mounting flange 50 is either a single flange that spans the perimeter, or a portion of the perimeter, of the pump housing 48. In other embodiments, the mounting flange 50 includes a plurality of individual flanges that extend from the pump housing 48. In one configuration, the number of individual flanges equals the number of screw used to secure the pump 40 to the mounting plate 30, as is shown in FIG. 3. Alternatively, the ratio of individual flanges to screws is not one-to-one.

Each mounting flange 50 includes a threaded hole 54, which is aligned with a corresponding threaded hole 38 in the mounting plate 30. The screw 60 is threaded through the threaded hole 54 and the threaded hole 38. Tightening the screws 60 compresses the sealing washers 62 between the flange 46 and the mounting plate 30, thereby sealing the fluid path between the pump 40 and the fluid radiator 20. As a group, the mounting flange 50, the screws 60, the threaded holes 54, and the threaded holes 38 comprise the mounting mechanism.

Alternative mounting mechanisms are also contemplated. For example, fasteners other than screws can be used. Alternative fasteners include, but are not limited to, rivets, cams, and spring clips. In other configurations, the pump housing and the mounting plate can be designed with threading, cams, or interlocks that enable the pump and the mounting plate to be locked together without the addition of any other intermediary fasteners.

Although the integrated pump assembly is shown as the pump coupled to the fluid radiator via single opening, alternative configurations are also contemplated in which the pump is coupled to the fluid radiator via multiple openings. Each flange can include multiple pump openings and/or the pump housing can include multiple flanges, each flange including one or more pump openings. Each pump opening is configured to lead to the pumping chamber within the pump. Each pump opening is aligned with a corresponding mounting plate opening and a radiator opening. A single mounting plate with multiple mounting plate openings can be used, or multiple mounting plates, each mounting plate with one or more mounting plate openings can be used. It is also contemplated that multiple pumps can be coupled to a single radiator, each pump including one or more pump openings.

An advantage of the integrated pump assembly is that the pump efficiency is improved. The configuration of the pump relative to the fluid radiator is such that the fluid path through the pump opening provides fluid to the center of the pumping chamber. The fluid path through the pump opening and into the pumping chamber is a straight path to the center of the pumping chamber, thus reducing the overall system load and improving system throughput. This results in a system with an increased efficiency.

The integrated pumping assembly provides many additional advantages including, but not limited to, the reduction of complexity by reduction of part count, the reduction of cost by reduction of part count, the reduction of vapor loss by the elimination of tubing, and/or sealing interfaces, and the reduction of required mechanical volume resulting from the elimination of superfluous mechanical assemblies.

The present invention has been described in terms of specific embodiments incorporating details to facilitate the understanding of the principles of construction and operation of the invention. Such reference herein to specific embodiments and details thereof is not intended to limit the scope of the claims appended hereto. It will be apparent to those skilled in the art that modifications may be made in the embodiment chosen for illustration without departing from the spirit and scope of the invention.

What is claimed is:

1. An integrated assembly comprising:
a. a pump including a first opening and a second opening through a pump housing;
b. a fluid radiator including a third opening through a radiator cap;
c. a mounting plate sealed to the radiator cap, wherein the mounting plate includes a fourth opening aligned with the third opening in the radiator cap, further wherein the mounting plate is coupled to the pump housing such that the first opening in the pump housing is aligned with the fourth opening in the mounting plate; and
d. a mounting mechanism coupled to the pump housing and to the mounting plate, wherein the mounting mechanism is configured to force the pump housing surrounding the first opening and the mounting plate surrounding the fourth opening against each other, thereby forming a sealed path through the first opening in the pump housing, the fourth opening in the mounting plate, and the third opening in the radiator cap.

2. The integrated assembly of claim 1 wherein the first opening in the pump housing is an inlet opening, the second opening in the pump housing is an outlet opening, and the third opening in the radiator cap is an outlet opening.

3. The integrated assembly of claim 1 wherein the first opening in the pump housing is an outlet opening, the second opening in the pump housing is an inlet opening, and the third opening in the radiator cap is an inlet opening.

4. The integrated assembly of claim 1 wherein the first opening is positioned in a first flange of the pump housing such that the first flange surrounds the first opening.

5. The integrated assembly of claim 4 wherein a portion of the first flange surrounding the first opening is configured as a flat surface and a portion of the mounting plate is configured as a flat surface, the flat surface of the mounting plate is configured to surround the fourth opening, and the integrated assembly further comprises one or more sealing washers positioned between the flat surface of the first flange and the flat surface of the mounting plate, wherein the one or more sealing washers surround the first opening and the fourth opening.

6. The integrated assembly of claim 4 wherein the first flange includes one or more grooves configured to surround the first opening, and the integrated assembly further comprises one or more sealing washers, one sealing washer positioned within each groove.

7. The integrated assembly of claim 4 wherein the mounting plate includes one or more grooves configured to surround the fourth opening, and the integrated assembly further comprises one or more sealing washers, one sealing washer positioned within each groove.

8. The integrated assembly of claim 4 wherein one or more of the sealing washers form a radial seal between the mounting plate and the pump housing.

9. The integrated assembly of claim 4 wherein one or more of the sealing washers form a face seal between the mounting plate and the pump housing.

10. The integrated assembly of claim 1 wherein the pump comprises a centrifugal pump.

11. The integrated assembly of claim 1 wherein the fluid radiator includes one or more fluid reservoirs, and the third opening in the radiator cap is configured to provide a fluid path to the one or more fluid reservoirs.

12. The integrated assembly of claim 1 wherein the mounting mechanism comprises a plurality of fastening mechanisms.

13. The integrated assembly of claim 12 wherein each of the plurality of fastening mechanisms is selected from a screw, a rivet, a cam, and a spring clip.

14. The integrated assembly of claim 12 wherein the pump housing further comprises one or more mounting flanges, each mounting flange coupled to one or more of the fastening mechanisms.

15. The integrated assembly of claim 1 wherein the mounting mechanism comprises a plurality of locking mechanisms.

16. The integrated assembly of claim 15 wherein each of the plurality of locking mechanisms is selected from a threading mechanism, a cam, and an interlocking mechanism.

17. The integrated assembly of claim 1 wherein the sealed path is configured to provide direct fluid flow between the pump and the fluid radiator.

18. The integrated assembly of claim 1 wherein the mounting plate is integrated to the radiator cap.

19. The integrated assembly of claim 1 wherein the mounting plate is blazed, welded, or epoxied integrated to the radiator cap.

20. An integrated assembly comprising:
a. a pump including a first opening and a second opening through a pump housing;
b. a heat exchanging device including a third opening through a device housing;
c. a mounting plate sealed to the device housing, wherein the mounting plate includes a fourth opening aligned with the third opening in the device housing, further wherein the mounting plate is coupled to the pump housing such that the first opening in the pump housing is aligned with the fourth opening in the mounting plate; and
d. a mounting mechanism coupled to the pump housing and to the mounting plate, wherein the mounting mechanism is configured to force the pump housing surrounding the first opening and the mounting plate surrounding the fourth opening against each other, thereby forming a sealed path through the first opening in the pump housing, the fourth opening in the mounting plate, and the third opening in the device housing.

21. The integrated assembly of claim 20 wherein the heat exchanging device comprises a fluid-based heat exchanging device.

22. The integrated assembly of claim 21 wherein the fluid-based heat exchanging device includes a thermal interface.

23. The integrated assembly of claim 22 further comprising a heat generating device coupled to the thermal interface.

24. The integrated assembly of claim 20 wherein the first opening in the pump housing is an inlet opening, the second opening in the pump housing is an outlet opening, and the third opening in the device housing is an outlet opening.

25. The integrated assembly of claim 20 wherein the first opening in the pump housing is an outlet opening, the second opening in the pump housing is an inlet opening, and the third opening in the device housing is an inlet opening.

26. The integrated assembly of claim 20 wherein the first opening is positioned in a first flange of the pump housing such that the first flange surrounds the first opening.

27. The integrated assembly of claim 26 wherein a portion of the first flange surrounding the first opening is configured as a flat surface and a portion of the mounting plate is configured as a flat surface, the flat surface of the mounting plate is configured to surround the fourth opening, and the integrated assembly further comprises one or more sealing washers positioned between the flat surface of the first flange and the flat surface of the mounting plate, wherein the one or more sealing washers surround the first opening and the fourth opening.

28. The integrated assembly of claim 26 wherein the first flange includes one or more grooves configured to surround the first opening, and the integrated assembly further comprises one or more sealing washers, one sealing washer positioned within each groove.

29. The integrated assembly of claim 26 wherein the mounting plate includes one or more grooves configured to surround the fourth opening, and the integrated assembly further comprises one or more sealing washers, one sealing washer positioned within each groove.

30. The integrated assembly of claim 26 wherein one or more of the sealing washers form a radial seal between the mounting plate and the pump housing.

31. The integrated assembly of claim 26 wherein one or more of the sealing washers form a face seal between the mounting plate and the pump housing.

32. The integrated assembly of claim 20 wherein the pump comprises a centrifugal pump.

33. The integrated assembly of claim 20 wherein the mounting mechanism comprises a plurality of fastening mechanisms.

34. The integrated assembly of claim 33 wherein each of the plurality of fastening mechanisms is selected from a screw, a rivet, a cam, and a spring clip.

35. The integrated assembly of claim 33 wherein the pump housing further comprises one or more mounting flanges, each mounting flange coupled to one or more of the fastening mechanisms.

36. The integrated assembly of claim 20 wherein the mounting mechanism comprises a plurality of locking mechanisms.

37. The integrated assembly of claim 36 wherein each of the plurality of locking mechanisms is selected from a threading mechanism, a cam, and an interlocking mechanism.

38. The integrated assembly of claim 20 wherein the sealed path is configured to provide direct fluid flow between the pump and the heat exchanging device.

39. The integrated assembly of claim 20 wherein the mounting plate is integrated to the radiator cap.

40. The integrated assembly of claim 20 wherein the mounting plate is blazed, welded, or epoxied to the radiator cap.
